(19) United States
(12) Patent Application Publication
(10) Pub. No.: US 2026/0082573 A1
(43) Pub. Date: Mar. 19, 2026

(54) SEMICONDUCTOR MEMORY DEVICE

(71) Applicant: Kioxia Corporation, Tokyo (JP)

(72) Inventor: Masaki UNNO, Fujisawa (JP)

(73) Assignee: Kioxia Corporation, Tokyo (JP)

(21) Appl. No.: 19/073,657

(22) Filed: Mar. 7, 2025

(30) Foreign Application Priority Data
Sep. 13, 2024 (JP) 2024-159294

(51) Int. Cl. H10B 43/40; G11C 16/26

(52) U.S. Cl. CPC H10B 43/40; G11C 16/26

(57) ABSTRACT

In a semiconductor memory device according to an embodiment, a second bit line includes a second inter-cell module wire that is electrically connected to a second memory cell and extends in a first direction toward a sense amplifier module from a position overlapping the second memory cell in an up-down direction, and a second intra-module wire that extends in a second direction side by side with the first intra-module wire in the first direction at a position close to the first intra-module wire and electrically connects the second inter-cell module wire and a second sense amplifier unit.

### CROSS-REFERENCE TO RELATED APPLICATIONS

This application is based upon and claims the benefit of priority from Japanese Patent Application No. 2024-159294, filed on Sep. 13, 2024; the entire contents of which are incorporated herein by reference.

### FIELD

Embodiments described herein relate generally to a semiconductor memory device.

### BACKGROUND

A semiconductor memory device includes, for example, a plurality of sense amplifier units that reads data of each of a plurality of memory cells. Since an individual memory cell is electrically connected to the corresponding sense amplifier unit, a bit line wire structure is complicated.

### BRIEF DESCRIPTION OF THE DRAWINGS

FIG. 1 is a block diagram of a semiconductor memory device according to an embodiment;

FIG. 2 is an equivalent circuit diagram illustrating an example of a configuration of a memory cell array included in the semiconductor memory device according to the embodiment;

FIG. 3 is a circuit diagram illustrating an example of a configuration of a sense amplifier unit and a latch circuit included in the semiconductor memory device according to the embodiment;

FIG. 4 is a circuit diagram illustrating an example of a configuration of a row decoder included in the semiconductor memory device according to the embodiment;

FIGS. 5A to 5C are cross-sectional views illustrating an example of a configuration of the semiconductor memory device according to the embodiment;

FIGS. 6A and 6B are diagrams illustrating an example of a wire structure that electrically connects pillars and the sense amplifier units according to the embodiment;

FIG. 7 is a schematic diagram illustrating an example of a configuration of a shield wire disposed in the vicinity of an intra-module wire according to the embodiment;

FIG. 8 is a schematic diagram illustrating another example of a configuration of the shield wire disposed in the vicinity of the intra-module wire according to the embodiment;

FIG. 9 is a layout diagram illustrating a connection relationship between pillars and sense amplifier units according to a comparative example;

FIGS. 10A and 10B are schematic diagrams three-dimensionally illustrating a connection relationship between pillars and sense amplifier units according to the embodiment and the comparative example;

FIGS. 11A and 11B are diagrams illustrating an example of a wire structure that electrically connects pillars and sense amplifier units included in a semiconductor memory device according to a first modification of the embodiment; and

FIGS. 12A and 12B are diagrams illustrating an example of a wire structure that electrically connects pillars and sense amplifier units included in a semiconductor memory device according to a second modification of the embodiment.

### DETAILED DESCRIPTION

A semiconductor memory device according to an embodiment includes: a memory cell array that includes a plurality of memory cells; a sense amplifier module that includes a plurality of sense amplifier units disposed at positions overlapping the memory cell array in an up-down direction and arranged in a first direction intersecting the up-down direction, the sense amplifier module having a width in the first direction narrower than a width of the memory cell array; and a plurality of bit lines that connects a sense amplifier unit among the plurality of sense amplifier units and a memory cell among the plurality of memory cells corresponding to each other, wherein the plurality of bit lines includes a first bit line connecting a first memory cell among the plurality of memory cells and a first sense amplifier unit corresponding to the first memory cell among the plurality of sense amplifier units, and a second bit line connecting a second memory cell among the plurality of memory cells and a second sense amplifier unit corresponding to the second memory cell among the plurality of sense amplifier units, the first bit line includes a first inter-cell module wire electrically connected to the first memory cell and extending in the first direction toward the sense amplifier module from a position overlapping the first memory cell in the up-down direction, and a first intra-module wire extending at a position overlapping the sense amplifier module in the up-down direction in a second direction intersecting the first direction and the up-down direction and electrically connecting the first inter-cell module wire and the first sense amplifier unit, and the second bit line includes a second inter-cell module wire electrically connected to the second memory cell and extending in the first direction toward the sense amplifier module from a position overlapping the second memory cell in the up-down direction, and a second intra-module wire extending at a position close to the first intra-module wire in the second direction side by side in the first direction with the first intra-module wire, and electrically connecting the second inter-cell module wire and the second sense amplifier unit.

Hereinafter, an embodiment of the present invention will be described in detail with reference to the drawings. Note that the present invention is not limited by the embodiment described below. In addition, constituent elements in the embodiment described below include those that can be easily assumed by those skilled in the art or those that are substantially the same.

### [Circuit Configuration of Semiconductor Memory Device]

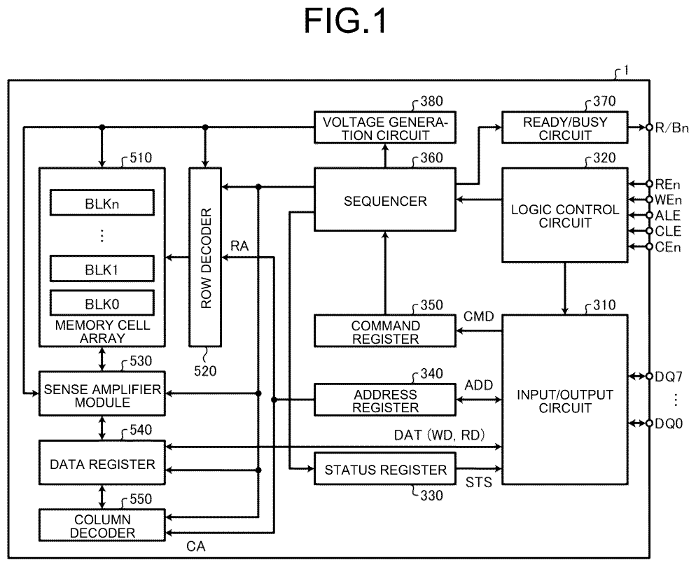

First, an example of a circuit configuration of a semiconductor memory device 1 according to an embodiment will be described with reference to FIGS. 1 to 4.

### (Overall Configuration of Semiconductor Memory Device)

FIG. 1 is a block diagram of the semiconductor memory device 1 according to an embodiment. As illustrated in FIG. 1, the semiconductor memory device 1 includes an input/output circuit 310, a logic control circuit 320, a status register 330, an address register 340, a command register 350, a sequencer 360, a ready/busy circuit 370, a voltage generation circuit 380, a memory cell array 510, a row decoder 520, a sense amplifier module 530, a data register 540, and a column decoder 550.

The input/output circuit 310 controls input/output of a signal DQ with an external device such as a memory controller, which is not illustrated, that controls the semiconductor memory device 1. The input/output circuit 310 includes an input circuit and an output circuit, which are not illustrated.

The input circuit transmits data DAT such as write data WDT received from the external device to the data register 540, transmits an address ADD to the address register 340, and transmits a command CMD to the command register 350.

The output circuit transmits status information STS received from the status register 330, data DAT such as read data RDT received from the data register 540, and the address ADD received from the address register 340 to the external device.

The logic control circuit 320 receives, for example, a chip enable signal CEn, a command latch enable signal CLE, an address latch enable signal ALE, a write enable signal WEn, and a read enable signal REn from the external device. In addition, the logic control circuit 320 controls the input/output circuit 310 and the sequencer 360 according to the received signal.

The status register 330 temporarily holds the status information STS in, for example, a write operation, a read operation, and an erase operation of data, and notifies the external device of whether or not the operation is normally ended.

The address register 340 temporarily holds the address ADD received from the external device via the input/output circuit 310. In addition, the address register 340 transfers a row address RA to the row decoder 520 and transfers a column address CA to the column decoder 550.

The command register 350 temporarily stores the command CMD received from the external device via the input/output circuit 310 and transfers the command CMD to the sequencer 360.

The sequencer 360 controls the entire operation of the semiconductor memory device 1. More specifically, the sequencer 360 controls, for example, the status register 330, the ready/busy circuit 370, the voltage generation circuit 380, the row decoder 520, the sense amplifier module 530, the data register 540, the column decoder 550, and the like according to the command CMD held by the command register 350, and executes a write operation, a read operation, an erase operation, and the like.

The ready/busy circuit 370 transmits a ready/busy signal R/Bn to the external device according to the operation status of the sequencer 360.

The voltage generation circuit 380 generates a voltage necessary for the write operation, the read operation, and the erase operation according to the control of the sequencer 360, and supplies the generated voltage to, for example, the memory cell array 510, the row decoder 520, the sense amplifier module 530, and the like. The row decoder 520 and the sense amplifier module 530 apply the voltage supplied from the voltage generation circuit 380 to the memory cells in the memory cell array 510.

The memory cell array 510 includes a plurality of blocks BLK (BLK0 to BLKn). The letter n is an integer of 2 or more. The block BLK is a set of a plurality of memory cells associated with bit lines and word lines, and is, for example, a data erasing unit. The memory cell is configured as, for example, a transistor, and holds nonvolatile data.

By including such a memory cell, the semiconductor memory device 1 is configured as, for example, a NAND nonvolatile memory.

The row decoder 520 decodes the row address RA. In addition, the row decoder 520 selects any block BLK on the basis of the decoding result. In addition, the row decoder 520 applies a necessary voltage to the block BLK.

The sense amplifier module 530 senses data read from the memory cell array 510 during the read operation. In addition, the sense amplifier module 530 transmits the read data RDT to the data register 540. During the write operation, the sense amplifier module 530 transmits the write data WDT to the memory cell array 510.

The data register 540 includes a plurality of latch circuits. The latch circuit holds the write data WDT and the read data RDT. For example, in the write operation, the data register 540 temporarily holds the write data WDT received from the input/output circuit 310 and transmits the write data WDT to the sense amplifier module 530. In addition, for example, in the read operation, the data register 540 temporarily holds the read data RDT received from the sense amplifier module 530 and transmits the read data RDT to the input/output circuit 310.

The column decoder 550 decodes the column address CA at the time of, for example, the write operation, the read operation, and the erase operation, and selects the latch circuit in the data register 540 according to the decoding result.

Note that a circuit group disposed around the memory cell array 510 is also referred to as a peripheral circuit. The peripheral circuit includes at least the row decoder 520, the sense amplifier module 530, the data register 540, and the column decoder 550. The peripheral circuit may include the status register 330, the address register 340, the command register 350, and the sequencer 360, and may further include the input/output circuit 310, the logic control circuit 320, the ready/busy circuit 370, and the voltage generation circuit 380.

As described above, the semiconductor memory device 1 includes the memory cell array 510 including the plurality of memory cells and the peripheral circuit that operates the plurality of memory cells.

### (Circuit Configuration of Memory Cell Array)

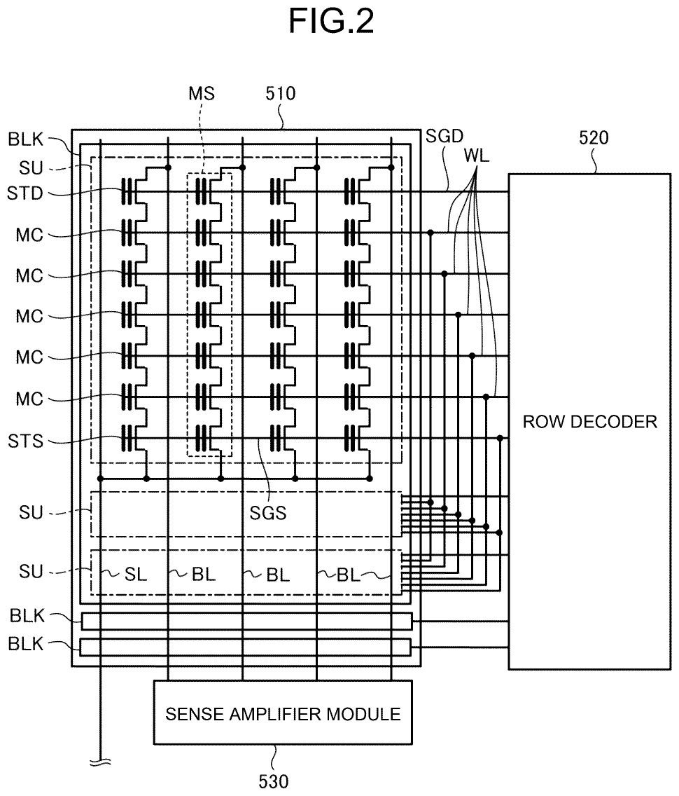

FIG. 2 is an equivalent circuit diagram illustrating an example of a configuration of the memory cell array 510 included in the semiconductor memory device 1 according to the embodiment.

The memory cell array 510 includes the plurality of blocks BLK as described above. Each of the plurality of blocks BLK includes a plurality of string units SU. Each of the plurality of string units SU includes a plurality of memory strings MS. Each of one ends of the plurality of memory strings MS is connected to the peripheral circuit such as the sense amplifier module 530 via a bit line BL. Each of the other ends of the plurality of memory strings MS is connected to the peripheral circuit via a common source line SL.

The memory string MS includes a drain select transistor STD, a plurality of memory cells MC, and a source select transistor STS connected in series between the bit line BL and the source line SL. Hereinafter, the drain select transistor STD and the source select transistor STS may be simply referred to as select transistors (STD and STS).

The memory cell MC is, for example, a field effect transistor (FET) including a charge storage layer in a gate insulating layer. The threshold voltage of the memory cell MC changes according to the charge amount in the charge storage layer. By providing one or a plurality of threshold voltages, the memory cell MC may be capable of storing data of one bit or a plurality of bits. Word lines WL are connected to the gate electrodes of the plurality of memory cells MC corresponding to one memory string MS. Each of these word lines WL is commonly connected to all the memory strings MS in one block BLK.

The select transistors (STD and STS) are, for example, field effect transistors. Select gate lines (SGD and SGS) are connected to gate electrodes of the select transistors (STD and STS). The drain select line SGD connected to the drain select transistor STD is provided corresponding to the string unit SU, and is commonly connected to all the memory strings MS in one string unit SU. The source select line SGS connected to the source select transistor STS is commonly connected to all the memory strings MS in one block BLK.

Each of one ends of the word lines WL and the select gate lines (SGD and SGS) is connected to the peripheral circuit such as the row decoder 520.

### (Circuit Configuration of Sense Amplifier Module)

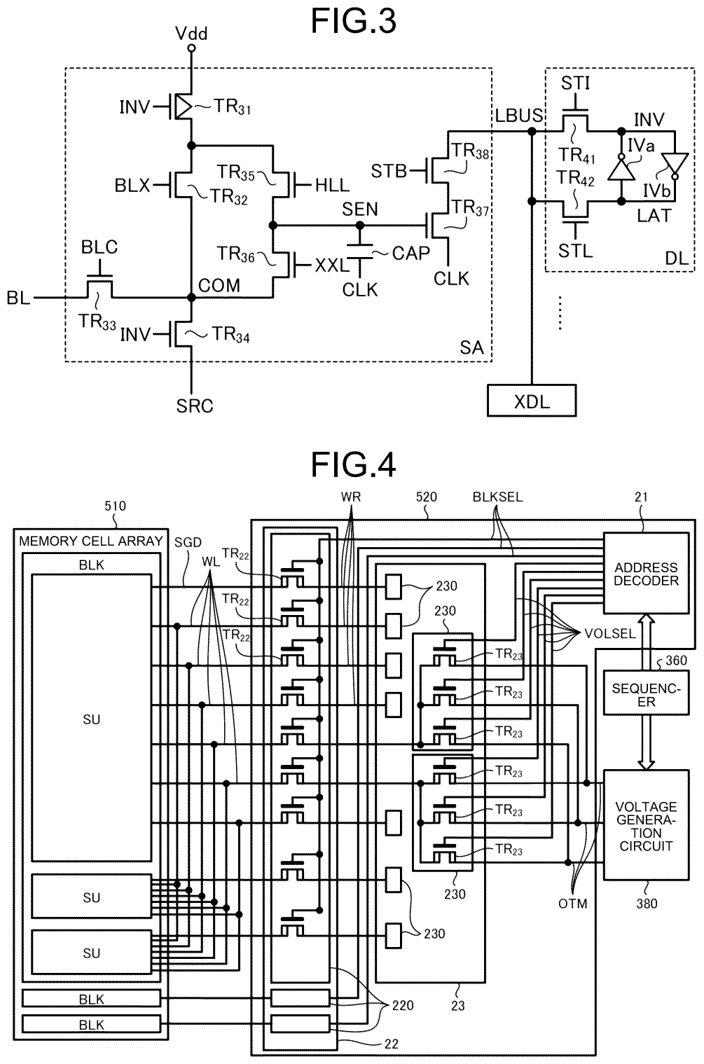

FIG. 3 is a circuit diagram illustrating an example of a configuration of a sense amplifier unit SA and a latch circuit DL or XDL included in the semiconductor memory device 1 according to the embodiment.

The sense amplifier module 530 described above includes a plurality of sense amplifier units SA provided for each bit line BL. For example, in the read operation, an individual sense amplifier unit SA senses data read to the corresponding bit line BL and determines whether the read data is “0” or “1”.

In addition, the above-described data register 540 includes a plurality of latch circuits DL and XDL corresponding to the plurality of sense amplifier units SA. The latch circuit XDL is also provided for each bit line BL. On the other hand, a plurality of latch circuits DL is provided for the corresponding sense amplifier unit SA. In this case, the number of the latch circuits DL is designed based on, for example, the number of bits of data that can be held by one memory cell MC. The latch circuits DL and XDL temporarily hold data related to the corresponding bit line BL.

FIG. 3 illustrates one sense amplifier unit SA in the sense amplifier module 530 and one latch circuit DL or XDL in the data register 540. Note that a plurality of control signals supplied to the sense amplifier unit SA and the like is controlled by the sequencer 360.

As illustrated in FIG. 3, the sense amplifier unit SA includes transistors TR₃₁ to TR₃₈ and a capacitor CAP. In the drawing, the transistor TR₃₁ is a low-breakdown-voltage, P-channel metal-oxide-semiconductor (MOS) transistor. In addition, the transistors TR₃₂ to TR₃₈ are low-breakdown-voltage, N-channel MOS transistors.

A low-breakdown-voltage CMOS transistor including the low-breakdown-voltage, P-channel MOS transistor and the low-breakdown-voltage, N-channel MOS transistor is a transistor to which a relatively low voltage is applied, and is also referred to as a low voltage (low voltage (LV), very low voltage (VLV)) MOS transistor.

One end of the transistor TR₃₁ is connected to a power supply line to which a power supply voltage Vdd is supplied, and a gate electrode of the transistor TR₃₁ is connected to a node INV. One end of the transistor TR₃₂ is connected to the other end of the transistor TR₃₁, the other end of the transistor TR₃₂ is connected to a node COM, and a control signal BLX is input to the gate electrode of the transistor TR₃₂. One end of the transistor TR₃₃ is connected to the node COM, the other end of the transistor TR₃₃ is connected to the corresponding bit line BL, and a control signal BLC is input to the gate electrode of the transistor TR₃₃.

One end of the transistor TR₃₄ is connected to the node COM, the other end of the transistor TR₃₄ is connected to a node SRC, and a gate electrode of the transistor TR₃₄ is connected to the node INV.

One end of the transistor TR₃₅ is connected to the other end of the transistor TR₃₁, the other end of the transistor TR₃₅ is connected to a node SEN, and a control signal HLL is input to the gate electrode of the transistor TR₃₅. One end of the transistor TR₃₆ is connected to the node SEN, the other end of the transistor TR₃₆ is connected to the node COM, and a control signal XXL is input to the gate electrode of the transistor TR₃₆.

A clock CLK is input to one end of the transistor TR₃₇, and a gate electrode of the transistor TR₃₇ is connected to the node SEN. One end of the transistor TR₃₈ is connected to the other end of the transistor TR₃₇, the other end of the transistor TR₃₈ is connected to a bus LBUS, and a control signal STB is input to the gate electrode of the transistor TR₃₈. One end of the capacitor CAP is connected to the node SEN, and the clock CLK is input to the other end of the capacitor CAP.

The latch circuit DL includes inverters IVa and IVb and transistors TR₄₁ and TR₄₂. In the drawing, the transistors TR₄₁ and TR₄₂ are low-breakdown-voltage, N-channel MOS transistors. Hereinafter, the transistors TR₄₁ and TR₄₂ included in the data register 540 may be simply referred to as transistors TR.

Note that although one latch circuit DL is illustrated in FIG. 3, the other latch circuits DL have a similar configuration.

The inverter IVa has an input terminal connected to a node LAT and an output terminal connected to the node INV. The inverter IVb has an input terminal connected to the node INV and an output terminal connected to the node LAT.

The transistor TR₄₁ has one end connected to the node INV, the other end connected to the bus LBUS, and a gate electrode to which a control signal STI is input. The transistor TR₄₂ has one end connected to the node LAT, the other end connected to the bus LBUS, and a gate electrode to which a control signal STL is input.

The latch circuit XDL has, for example, a configuration substantially similar to that of the latch circuit DL, and is connected to the bus LBUS so as to be able to transmit and receive data to and from the sense amplifier unit SA and the latch circuit DL. In addition, the latch circuit XDL is connected to the input/output circuit 310 described above, and is used for input/output of data between the sense amplifier unit SA and the input/output circuit 310.

In addition, the latch circuit XDL is also used for a cache operation of the semiconductor memory device 1. That is, even if all the latch circuits DL corresponding to the sense amplifier unit SA are in use, the semiconductor memory device 1 can receive data from the outside as long as the latch circuit XDL is vacant.

As described above, the sense amplifier unit SA belonging to the peripheral circuit and the latch circuits DL and XDL include the plurality of transistors TR.

Next, an operation of the sense amplifier unit SA having the above configuration will be briefly described.

As an example of the case of writing data to the memory cell MC, in a case where a charge is injected into the memory cell MC to increase the threshold, an “H” level (“1” data) is stored in the node INV of the latch circuit DL. As a result, the transistor TR₃₄ is turned on, and the bit line BL is set to 0 V.

As another example of the case of writing data to the memory cell MC, in a case where a charge is not injected into the memory cell MC and the threshold is not changed, an “L” level (“0” data) is stored in the node INV of the latch circuit DL. As a result, the transistor TR₃₁ is turned on, and a predetermined positive voltage is applied to the bit line BL.

At the time of reading, the node INV is set to the “L” level, and the transistor TR₃₁ is turned on. In addition, the bit line BL is pre-charged by the transistor TR₃₁ via the transistors TR₄₁ and TR₄₂. In addition, the transistor TR₃₅ is also turned on, and the node SEN is charged to a predetermined potential.

Thereafter, the transistor TR₃₅ is turned off, the signal XXL is set to the “H” level, and the transistor TR₃₆ is turned on. Thus, when the corresponding memory cell MC is turned on, the potential of the node SEN decreases, and the transistor TR₃₇ is turned off. On the other hand, when the corresponding memory cell MC is turned off, the potential of the node SEN maintains the “H” level, and the transistor TR₃₇ is turned on.

In addition, the transistor TR₃₈ is turned on by the signal STB, and a potential corresponding to on/off of the transistor TR₃₇ is read to the bus LBUS and held in the latch circuit DL.

Note that the circuit configuration of the sense amplifier unit SA and the latch circuits DL and XDL illustrated in FIG. 3 is an example, and the sense amplifier unit SA and the latch circuits DL and XDL can adopt various configurations other than the above. Therefore, the number and types of the transistors TR included in the sense amplifier unit SA and the latch circuits DL and XDL can be variously different. For example, the sense amplifier unit SA and the latch circuits DL and XDL may be configured to include a high-breakdown-voltage, P-channel MOS transistor, a high-breakdown-voltage, N-channel MOS transistor, or the like.

### (Circuit Configuration of Row Decoder)

FIG. 4 is a circuit diagram illustrating an example of a configuration of the row decoder 520 included in the semiconductor memory device 1 according to the embodiment.

As illustrated in FIG. 4, the row decoder 520 includes an address decoder 21, a block select circuit 22, and a voltage select circuit 23.

The address decoder 21 includes a plurality of block select lines BLKSEL and a plurality of voltage select lines VOLSEL.

The address decoder 21 refers to the address data of the address register 340 included in the above-described peripheral circuit, for example, in accordance with a control signal from the sequencer 360.

In addition, the address decoder 21 decodes the referred address data, turns on a transistor TRE and a transistor TR₂₃ corresponding to the address data, and turns off the other transistors TR₂₂ and TR₂₃. Note that the transistors TR₂₂ and the transistors TR₂₃ are transistors included in the block select circuit 22 and the voltage select circuit 23 described below, respectively.

In addition, the address decoder 21 sets the voltages of the block select line BLKSEL and the voltage select line VOLSEL corresponding to the address data to, for example, an “H” state, and sets the other voltages to an “L” state. Note that the voltages applied to these wires are reversed depending on whether an N-channel transistor or a P-channel transistor is used for the block select circuit 22 and the voltage select circuit 23. The above voltage is an example in a case where the transistor is an N-channel type.

In the example of FIG. 4, in the address decoder 21, one block select line BLKSEL is provided for one block BLK in the memory cell array 510. However, this configuration can be changed as appropriate. For example, one block select line BLKSEL may be provided for two or more blocks BLK.

The block select circuit 22 includes a plurality of block select units 220 corresponding to the blocks BLK of the memory cell array 510. Each of the plurality of block select units 220 includes a plurality of transistors TR₂₂ corresponding to the word lines WL and the select gate lines (SGD and SGS).

The transistor TR₂₂ is a high-breakdown-voltage, N-channel MOS transistor, and functions as a block driving transistor. The drain electrodes of the transistors TRE are electrically connected to the corresponding word lines WL or select gate lines (SGD and SGS). Source electrodes of the transistors TR₂₂ are electrically connected to voltage output terminals OTM via wires WR and the voltage select circuit 23. The gate electrodes of the transistors TR₂₂ are commonly connected to the corresponding block select line BLKSEL.

In addition, the block select circuit 22 further includes a plurality of transistors, which is not illustrated. The plurality of transistors is high-breakdown-voltage CMOS transistors connected between the select gate lines (SGD and SGS) and a ground voltage supply terminal. The plurality of transistors causes the select gate lines (SGD and SGS) included in an unselected block BLK in the memory cell array 510 to conduct with the ground voltage supply terminal. Note that the plurality of word lines WL included in the unselected block BLK is set to a floating state.

The voltage select circuit 23 includes a plurality of voltage select units 230 corresponding to the word lines WL and the select gate lines (SGD and SGS). Each of the plurality of voltage select units 230 includes a plurality of transistors TR₂₃.

The transistor TR₂₃ is a high-breakdown-voltage, N-channel MOS transistor, and functions as a voltage select transistor. Drain terminals of the transistors TR₂₃ are electrically connected to the corresponding word lines WL or select gate lines (SGD and SGS) via the wires WR and the block select circuit 22. Each of the source terminals is electrically connected to the corresponding voltage output terminal OTM. Each of the gate electrodes is connected to the corresponding voltage select line VOLSEL.

A high-breakdown-voltage CMOS transistor including the high-breakdown-voltage, P-channel MOS transistor and the high-breakdown-voltage, N-channel MOS transistor is a transistor to which a relatively high voltage is applied, and is also referred to as a high voltage (high voltage (HV)) MOS transistor.

As described above, the row decoder 520 belonging to the peripheral circuit includes the plurality of transistors TR₂₂, TR₂₃, and the like. However, the circuit configuration of the row decoder 520 illustrated in FIG. 4 is an example, and the number and types of the transistors TR₂₂, TR₂₃, and the like included in the row decoder 520 can be variously different.

### [Physical Configuration of Semiconductor Memory Device]

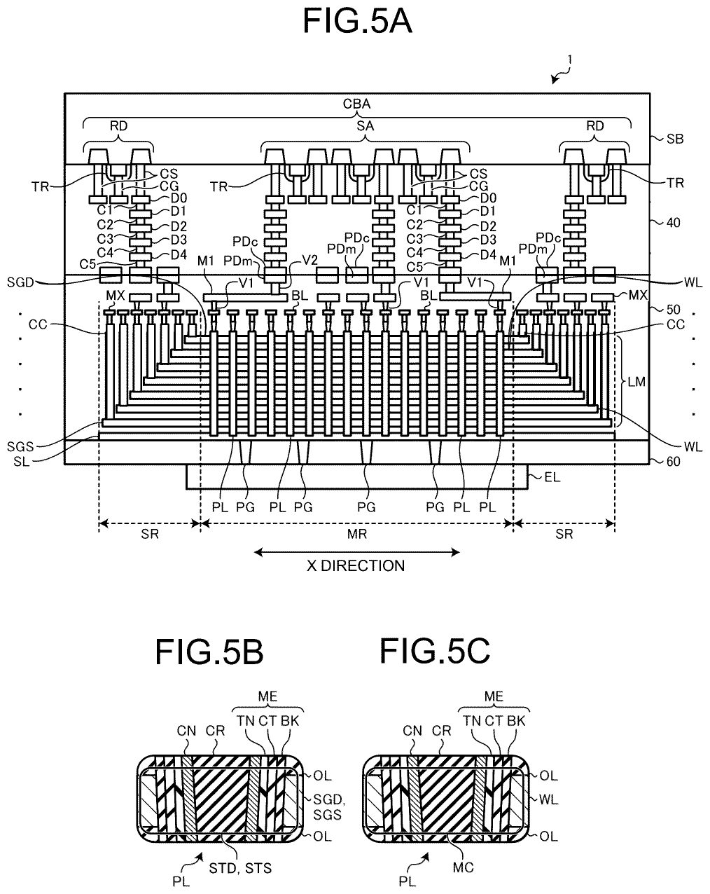

Next, an example of a physical configuration of the semiconductor memory device 1 according to the embodiment will be described with reference to FIGS. 5A to 5C. FIGS. 5A to 5C are cross-sectional views illustrating an example of a configuration of the semiconductor memory device 1 according to the embodiment.

More specifically, FIG. 5A is a cross-sectional view of the semiconductor memory device 1 along an X direction. Note that, in FIG. 5A, hatching is omitted in consideration of visibility of the drawing. FIGS. 5B and 5C are partially enlarged cross-sectional views of a pillar PL included in the semiconductor memory device 1, FIG. 5B illustrates a cross section at a height position of the select gate line SGD or SGS, and FIG. 5C illustrates a cross section at a height position of the word line WL.

As illustrated in FIG. 5A, the semiconductor memory device 1 includes an electrode film EL, a source line SL, one or more select gate lines SGS, a plurality of word lines WL, one or more select gate lines SGD, and a semiconductor substrate SB in which a peripheral circuit CBA is provided in order from the lower side of the drawing.

The source line SL is disposed on the electrode film EL via an insulating layer 60. A plurality of plugs PG is disposed in the insulating layer 60, and the source line SL and the electrode film EL maintain electrical conduction via the plugs PG. Although not illustrated, an electrode pad for supplying power and a signal from the outside to the semiconductor memory device 1 is provided in the same layer as the electrode film EL.

The select gate lines SGS, the plurality of word lines WL, and the select gate lines SGD are stacked in this order on the source line SL to constitute a stacked body LM. The plurality of word lines WL and the select gate lines SGD and SGS are, for example, a tungsten layer or a molybdenum layer.

A memory cell array MR is disposed at a central portion of the plurality of word lines WL in the X direction, and staircase regions SR are disposed at both end portions of the plurality of word lines WL in the X direction. The memory cell array MR illustrated in FIG. 5A has a physical configuration corresponding to the memory cell array 510 illustrated in FIG. 1 and the like described above.

The stacked body LM including the memory cell array MR and the staircase regions SR is covered with an insulating layer 50. The insulating layer 50 also extends around the stacked body LM.

The memory cell array MR and the staircase regions SR are divided into the above-described plurality of blocks BLK (see FIG. 1 and the like) by a plurality of plate-like portions, which is not illustrated, penetrating the plurality of word lines WL and the like and extending in the direction along the X direction.

In addition, between the plate-like portions adjacent to each other in a Y direction, a plurality of separation layers, which is not illustrated, penetrating the select gate line SGD extends in the direction along the X direction. The plurality of separation layers extends in the direction along the X direction over the entire memory cell array MR and reaches a part of the staircase regions SR at both end portions in the X direction.

As a result, in one block BLK, the select gate line SGD is separated into a plurality of regions. In other words, the separation layers penetrate the portions above the plurality of word lines WL of the stacked body LM, so that these upper layer portions are partitioned into patterns of the plurality of select gate lines SGD.

In the memory cell array MR, a plurality of pillars PL penetrating the word lines WL and the select gate lines SGD and SGS in the stacking direction is disposed. A lower end portion of the pillar PL is connected to the source line SL, and an upper end portion of the pillar PL is connected to the bit line BL via a plug or the like.

As illustrated in FIGS. 5B and 5C, the pillar PL includes a memory layer ME and a channel layer CN in order from the outer peripheral side of the pillar PL. The memory layer ME has a multilayer structure in which a block insulating layer BK, a charge storage layer CT, and a tunnel insulating layer TN are stacked in order from the outer peripheral side of the pillar PL. A core layer CR is loaded further inside the channel layer CN.

The block insulating layer BK, the tunnel insulating layer TN, and the core layer CR are, for example, silicon oxide layers or the like. The charge storage layer CT is, for example, a silicon nitride layer or the like. The channel layer is, for example, a semiconductor layer such as a polysilicon layer or a single crystal silicon layer.

As illustrated in FIG. 5C, with the above configuration, a memory cell MC is formed in each portion facing the individual word lines WL on the side surface of the pillar PL. When a predetermined voltage is applied from the word line WL, data is written to and read from the memory cell MC. Note that the individual word lines WL are insulated from each other by an insulating layer OL such as a silicon oxide layer.

As described above, the memory cells MC are formed at the intersection positions of the pillars PL and the plurality of word lines WL, whereby the semiconductor memory device 1 is configured as a three-dimensional nonvolatile memory in which the memory cells MC are three-dimensionally disposed in the memory cell array MR, for example. In addition, the pillars PL in which the memory cells MC are formed at intersection positions with the plurality of word lines WL are physical configurations corresponding to the above-described memory strings MS (see FIG. 2 and the like).

As illustrated in FIG. 5B, a select gate STD is formed in a portion where the side surface of the pillar PL faces the select gate line SGD above the word line WL. In addition, a select gate STS is formed in a portion where the side surface of the pillar PL faces the select gate line SGS below the word line WL.

When predetermined voltages are applied from the select gate lines SGD and SGS, the select gates STD and STS are turned on or off, and the memory cells MC of the pillar PL to which the select gates STD and STS belong can be brought into a selected state or a non-selected state. Note that the select gate lines SGD and SGS are also insulated by insulating layers OL disposed on both sides in the stacking direction of the stacked body LM.

The aforementioned bit lines BL extend above the plurality of pillars PL in the Y direction orthogonal to the X direction, that is, in the direction perpendicular to the plane of the paper, across the plurality of blocks BLK. As a result, a plurality of pillars PL belonging to different blocks BLK and arranged in the Y direction is connected to one bit line BL.

The bit line BL is connected to a wire M1 above the bit line BL via a plug V1. The wire M1 is connected to a pad PDm disposed on the upper surface of the insulating layer 50 covering the stacked body LM via a plug V2.

In the staircase regions SR, the plurality of word lines WL and the select gate lines SGD and SGS are processed in a staircase shape and terminate. At this time, as the distance from the memory cell array MR increases in the X direction, the plurality of word lines WL and the select gate lines SGD and SGS constituting terrace portions shift from the upper layer side to the lower layer side, so that the height position of the terrace portion lowers toward the source line SL side.

Contacts CC connected to the word lines WL and the select gate lines SGD and SGS of layers are disposed at terrace portions of steps including the plurality of word lines WL and the select gate lines SGD and SGS.

The word lines WL and the like stacked in multiple layers are individually lead out by these contacts CC. More specifically, a write voltage, a read voltage, and the like are applied from these contacts CC to the memory cells MC included in the memory cell array MR at the central portion of the plurality of word lines WL via the word lines WL at the same height positions as the memory cells MC.

An upper end portion of an individual contact CC is connected to a wire MX via a plug or the like. The wires MX are disposed in the same layer as the above-described bit lines BL. The wire MX is also connected to the wire M1 above the wire MX via the corresponding plug V1. The wire M1 is connected to the pad PDm disposed on the upper surface of the insulating layer 50 via the plug V2.

The semiconductor substrate SB above the insulating layer 50 is, for example, a silicon substrate or the like. The peripheral circuit CBA including transistors TR, contacts CG and CS, and the like are disposed on the surface of the semiconductor substrate SB. As described above, the peripheral circuit CBA includes the sense amplifier unit SA, row decoders RD, and the like configured by the plurality of transistors TR included in the peripheral circuit CBA. Note that the row decoder RD illustrated in FIG. 5A has a physical configuration corresponding to the row decoder 520 illustrated in FIG. 1 and the like described above.

The peripheral circuit CBA is covered with an insulating layer 40. In the insulating layer 40, wires D0 to D4 are disposed in this order from the peripheral circuit CBA side toward the surface of the insulating layer 40. These wires D0 to D4 belong to different layers.

The wires D0 to D4 are connected to each other by plugs C1 to C4 disposed between the wires D0 to D4, respectively. Among the wires D0 to D4, the wire D4 disposed closest to the surface of the insulating layer 40 is connected to a pad PDc disposed on the surface of the insulating layer 40 via a plug C5.

The insulating layer 40 covering the peripheral circuit CBA and the insulating layer 50 covering the stacked body LM and the like are bonded on the surfaces of each other, whereby the pads PDm and PDc are connected to each other. In addition, as a result, the configurations of the plurality of word lines WL, the select gate lines SGD and SGS, the pillars PL, the contacts CC, and the like are electrically connected to the peripheral circuit CBA.

Various voltages applied from the contacts CC to the memory cells MC are controlled by the peripheral circuit CBA electrically connected to the contacts CC. More specifically, the contacts CC are electrically connected to the row decoders RD and the like included in the peripheral circuit CBA, and electrically operate the memory cells MC by various voltages supplied from the row decoders RD.

In addition, the data of the memory cells MC is read to the peripheral circuit CBA electrically connected to the bit lines BL. More specifically, the bit lines BL are electrically connected to the sense amplifier unit SA and the like included in the peripheral circuit CBA, and data of the memory cells MC is read by the sense amplifier unit SA.

The row decoders RD of the peripheral circuit CBA are preferably disposed at a position overlapping, in an up-down direction, the staircase regions SR of the stacked body LM to which the contacts CC are connected. In addition, the sense amplifier unit SA is preferably disposed at a position overlapping, in the up-down direction, the memory cell array MR of the stacked body LM in which the pillars PL are disposed.

However, as described above, the row decoders RD are configured to include the block select units 220, the voltage select units 230 (see FIG. 4 and the like), and the like for individual word lines WL. Therefore, on the semiconductor substrate SB, the row decoders RD occupy a larger area than the sense amplifier module 530 including the plurality of sense amplifier units SA and the like.

As a result, the row decoders RD are disposed on the semiconductor substrate SB not only in a region overlapping the staircase regions SR of the stacked body LM in the up-down direction but also in, for example, a partial region overlapping the memory cell array MR in the up-down direction.

As a result, the sense amplifier module 530 is collectively disposed in a region corresponding to the central portion of the memory cell array MR in the X direction within the region overlapping the memory cell array MR in the up-down direction on the semiconductor substrate SB. In other words, the width in the X direction of the region occupied by the sense amplifier module 530 on the semiconductor substrate SB is narrower than the width in the X direction of the region occupied by the memory cell array MR in the stacked body LM.

In addition, by the above-described disposition of the sense amplifier module 530, some pillars PL among the plurality of pillars PL disposed in the memory cell array MR are disposed at positions not overlapping the sense amplifier module 530 in the up-down direction.

Therefore, in the semiconductor memory device 1 of the embodiment, the wire M1 above the bit lines BL connected to the upper end portions of the pillars PL is extended, for example, in the X direction from the disposition position of the bit lines BL to the position below the corresponding sense amplifier unit SA, and the pillars PL and the corresponding sense amplifier unit SA are electrically connected.

### [Wire Structure of Semiconductor Memory Device]

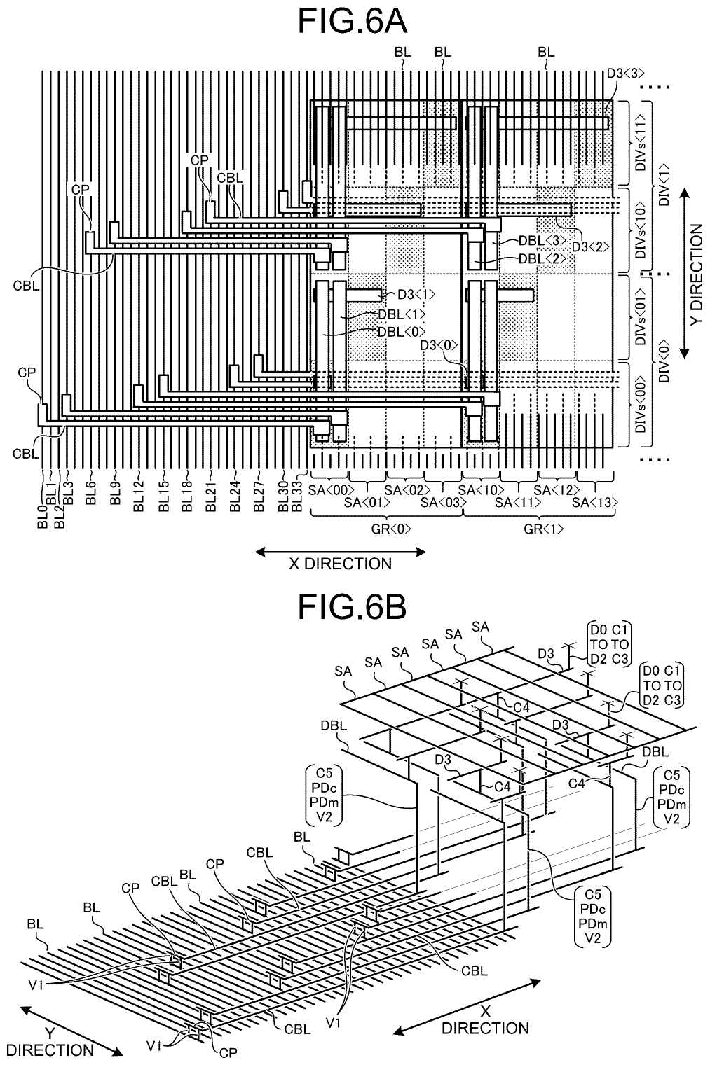

Next, a connection relationship between the pillars PL and the sense amplifier units SA according to the embodiment will be described with reference to FIGS. 6A to 8.

FIGS. 6A and 6B are diagrams illustrating an example of a wire structure that electrically connects the pillars PL and the sense amplifier units SA according to the embodiment.

More specifically, FIG. 6A is a layout diagram illustrating a connection relationship between the pillars PL and the sense amplifier units SA, and illustrates a state in which the sense amplifier unit SA side is viewed from the memory cell array MR side among the memory cell array MR and the sense amplifier units SA disposed in the up-down direction.

However, in FIG. 6A, inter-cell module wires CBL located closer to the sense amplifier units SA than the bit lines BL are illustrated on the front side of the drawing than the bit lines BL in consideration of visibility of the drawing.

FIG. 6B is a schematic diagram three-dimensionally illustrating a connection relationship between the pillars PL and the sense amplifier units SA.

Note that, in the present specification, both the X direction and the Y direction are directions along the orientation of the surfaces of the word lines WL, and the X direction and the Y direction are orthogonal to each other. In addition, the electrical lead-out direction of the word lines WL may be referred to as a first direction, and the first direction is a direction along the X direction. In addition, a direction intersecting the first direction may be referred to as a second direction, and the second direction is a direction along the Y direction. However, since the semiconductor memory device 1 may include a manufacturing error, the first direction and the second direction are not necessarily orthogonal to each other.

As illustrated in FIGS. 6A and 6B, the plurality of sense amplifier units SA extends a predetermined distance in the direction along the Y direction, and is disposed side by side in the X direction. These sense amplifier units SA are divided into a plurality of groups GR for two or more sense amplifier units SA adjacent in the X direction from the viewpoint of electrical control.

As an example, one group GR includes four sense amplifier units SA, and FIGS. 6A and 6B illustrate two groups GR<0> and GR<1> of sense amplifier units SA<00> to SA<03> and sense amplifier units SA<10> to SA<13>.

In addition, the plurality of sense amplifier units SA is divided into a plurality of regions DIV in the Y direction from the viewpoint of electrical control. As an example, the plurality of sense amplifier units SA is divided into two regions DIV<0> and DIV<1> in the Y direction, and these regions DIV<0> and DIV<1> are divided into sub-regions DIVs<00> and DIVs<01> and sub-regions DIVs<10> and DIVs<11>, respectively.

The plurality of bit lines BL extends in the direction along the Y direction, and is disposed side by side in the X direction. Note that the left side of the drawings of FIGS. 6A and 6B is a region where the bit lines BL that do not overlap the plurality of sense amplifier units SA in the up-down direction are disposed. Accordingly, the sense amplifier units SA corresponding to these bit lines BL are disposed to be shifted in the rightward direction in the drawing with respect to the bit lines BL.

In addition, the right side of the drawings of FIGS. 6A and 6B is a region where the plurality of sense amplifier units SA and the bit lines BL are disposed to overlap each other in the up-down direction. However, the sense amplifier units SA illustrated in FIGS. 6A and 6B are disposed in the vicinity of the end in the X direction in the sense amplifier module 530 described above, and the sense amplifier units SA corresponding to the bit lines BL overlapping these sense amplifier units SA in the up-down direction are also disposed to be shifted in the rightward direction in the drawing with respect to the bit lines BL. Note that the sense amplifier units SA corresponding to the bit lines BL are not illustrated in FIGS. 6A and 6B.

These bit lines BL and the sense amplifier units SA shifted in the rightward direction in the drawing are electrically connected by inter-cell module wires CBL extending in the X direction from the disposition position of the bit lines BL toward the sense amplifier units SA.

More specifically, one end portions of the inter-cell module wires CBL are connected to the bit lines BL via the plugs V1, and the other end portions are connected to intra-module wires DBL disposed in a predetermined region of the plurality of sense amplifier units SA via the plugs V2, the pads PDm and PDC, and the plugs C5.

Note that in order to improve the reliability of connection between the bit lines BL and the inter-cell module wires CBL, the plurality of plugs V1 may be interposed therebetween. For example, by securing a long connection portion CP between each inter-cell module wire CBL and the corresponding bit line BL in the Y direction, the number of plugs V1 connecting them can be increased, and the reliability of the electrical connection can be enhanced.

In addition, the inter-cell module wire CBL is one type of the above-described wire M1. That is, among the wires M1 connecting the bit line BL and the sense amplifier unit SA or the aforementioned contact CC and the row decoder RD, the inter-cell module wire CBL corresponds to the wire M1 connecting the bit line BL and the sense amplifier unit SA.

In addition, the intra-module wire DBL is one type of the above-described wire D4. That is, among the wires D4 connecting the bit line BL and the sense amplifier unit SA or the aforementioned contact CC and the row decoder RD, the intra-module wire DBL corresponds to the wire D4 connecting the bit line BL and the sense amplifier unit SA.

In the example of FIGS. 6A and 6B, four intra-module wires DBL are disposed in one group GR including four sense amplifier units SA. Among them, two intra-module wires DBL<0> and DBL<1> are adjacent to each other in the X direction, and extend in the Y direction in the region DIV<0> across the two sub-regions DIVs<00> and DIVs<01>. In addition, two intra-module wires DBL<2> and DBL<3> are adjacent to each other in the X direction, and extend in the Y direction in the region DIV<1> across the two sub-regions DIVs<10> and DIVs<11>.

In other words, the plurality of regions DIV dividing the sense amplifier units SA in the Y direction is allocated to each intra-module wire DBL disposed side by side in the Y direction in one group GR according to the extending position and the extending distance of the intra-module wires DBL.

Among the intra-module wires DBL disposed across the two sub-regions DIVs<00> and DIVs<01>, one intra-module wire DBL is connected to the corresponding inter-cell module wire CBL in the sub-region DIVs<00>, and is connected to a wire D3<0> disposed in the sub-region DIVs<00> via the plug C4. The wire D3<0> is connected to the sense amplifier unit SA immediately below the wire D3<0> via the wires DO to D2 and the plugs C1 to C3.

Among the intra-module wires DBL disposed across the two sub-regions DIVs<00> and DIVs<01>, another intra-module wire DBL is connected to the corresponding inter-cell module wire CBL in the sub-region DIVs<00>, and is connected to a wire D3<1> disposed in the sub-region DIVs<01> via the plug C4. The wire D3<1> extends in the direction along the X direction and is connected to the sense amplifier unit SA adjacent in the X direction to the sense amplifier unit SA to which the wire D3<0> is connected via the wires D0 to D2 and the plugs C1 to C3 in the sub-region DIVs<01>.

Among the intra-module wires DBL disposed across the two sub-regions DIVs<10> and DIVs<11>, one intra-module wire DBL is connected to the corresponding inter-cell module wire CBL in the sub-region DIVs<10>, and is connected to a wire D3<2> disposed in the sub-region DIVs<10> via the plug C4. The wire D3<2> is connected to the sense amplifier unit SA adjacent in the X direction to the sense amplifier unit SA to which the wire D3<1> is connected via the wires DO to D2 and the plugs C1 to C3 in the sub-region DIVs<10>.

Among the intra-module wires DBL disposed across the two sub-regions DIVs<10> and DIVs<11>, another intra-module wire DBL is connected to the corresponding inter-cell module wire CBL in the sub-region DIVs<10>, and is connected to a wire D3<3> disposed in the sub-region DIVs<11>. The wire D3<3> extends in the direction along the X direction and is connected to the sense amplifier unit SA adjacent in the X direction to the sense amplifier unit SA to which the wire D3<2> is connected via the wires D0 to D2 and the plugs C1 to C3 in the sub-region DIVs<11>.

With the above configuration, the predetermined bit line BL and the sense amplifier unit SA shifted in the rightward direction in the drawing with respect to the bit line BL are electrically connected.

In the example of FIGS. 6A and 6B, a bit line BL0 is connected to the intra-module wire DBL<0> disposed across the sub-regions DIVs<00> and DIVs<01> of the sense amplifier unit <00> in the sub-region DIVs<00> via the inter-cell module wire CBL, and is further connected to the sense amplifier unit SA<00> in the sub-region DIVs<00> via the wire D3<0>.

In addition, a bit line BL3 is connected to the intra-module wire DBL<1> disposed in the sense amplifier unit <00> adjacent to the intra-module wire DBL<0> in the X direction in the sub-region DIVs<01> via the inter-cell module wire CBL, and is further connected to the sense amplifier unit SA<01> in the sub-region DIVs<01> via the wire D3<1>.

In addition, a bit line BL18 is connected to the intra-module wire DBL<2> disposed across the sub-regions DIVs<10> and DIVs<11> of the sense amplifier unit <10> in the sub-region DIVs<10> via the inter-cell module wire CBL, and is further connected to the sense amplifier unit SA<12> in the sub-region DIVs<10> via the wire D3<2>.

In addition, a bit line BL21 is connected to the intra-module wire DBL<3> disposed in the sense amplifier unit <10> adjacent to the intra-module wire DBL<2> in the X direction in the sub-region DIVs<11> via the inter-cell module wire CBL, and is further connected to the sense amplifier unit SA<13> in the sub-region DIVs<11> via the wire D3<3>.

In FIGS. 6A and 6B, the sub-regions DIVs in the sense amplifier units SA in which the plurality of bit lines BL is connected to the corresponding sense amplifier units SA are highlighted.

In addition, the inter-cell module wires CBL connected to bit lines BL24 and BL27 extend in the X direction at a position overlapping the sub-region DIVs<00> of the plurality of sense amplifier units SA in the up-down direction, and are connected to sense amplifier units SA not illustrated in FIGS. 6A and 6B.

In addition, the inter-cell module wires CBL connected to bit lines BL30 and BL33 extend in the X direction at a position overlapping the sub-region DIVs<10> of the plurality of sense amplifier units SA in the up-down direction, and are connected to sense amplifier units SA not illustrated in FIGS. 6A and 6B.

As described above, the inter-cell module wires CBL connected to the plurality of bit lines BL0, BL3, BL12, BL15, BL24, BL27, and the like are collectively disposed at positions overlapping the sub-region DIVs<00> of the plurality of sense amplifier units SA in the up-down direction, and the inter-cell module wires CBL connected to the plurality of bit lines BL6, BL9, BL18, BL21, BL30, BL33, and the like are collectively disposed at positions overlapping the sub-regions DIVs<10> of the plurality of sense amplifier units SA in the up-down direction.

As a result, in the layer between the plurality of inter-cell module wires CBL and the plurality of intra-module wires DBL, the plugs V2, the pads PDm and PDc, and the plugs C5 are collected at positions overlapping the sub-region DIVs<00> and the sub-region DIVs<10> of the plurality of sense amplifier units SA in the up-down direction, and a sufficient space is secured in the layer between the plurality of inter-cell module wires CBL and the plurality of intra-module wires DBL.

Note that, in FIGS. 6A and 6B, the bit lines BL1, BL2, BL4, BL5 . . . . BL10, BL11 . . . . BL25, BL26 . . . , and the like to which the inter-cell module wire CBL and the like are not connected are connected to a plurality of sense amplifier units SA, which are not illustrated, disposed at positions separated from the plurality of sense amplifier units SA illustrated in FIG. 6 in the Y direction.

In addition, in the present specification, the entire bit lines BL, inter-cell module wires CBL, and intra-module wires DBL may be referred to as bit lines in a broad sense. In addition to the bit lines BL, the inter-cell module wires CBL, and the intra-module wires DBL, the plugs V1, V2, C5, and the like connecting these may be included in the bit lines, and further, the pads PDm and PDc connecting the inter-cell module wires CBL and the intra-module wires DBL may be included in the bit lines.

In addition, in the memory cell array MR, the bit lines BL connected to the plurality of pillars PL are an example of intra-cell wires.

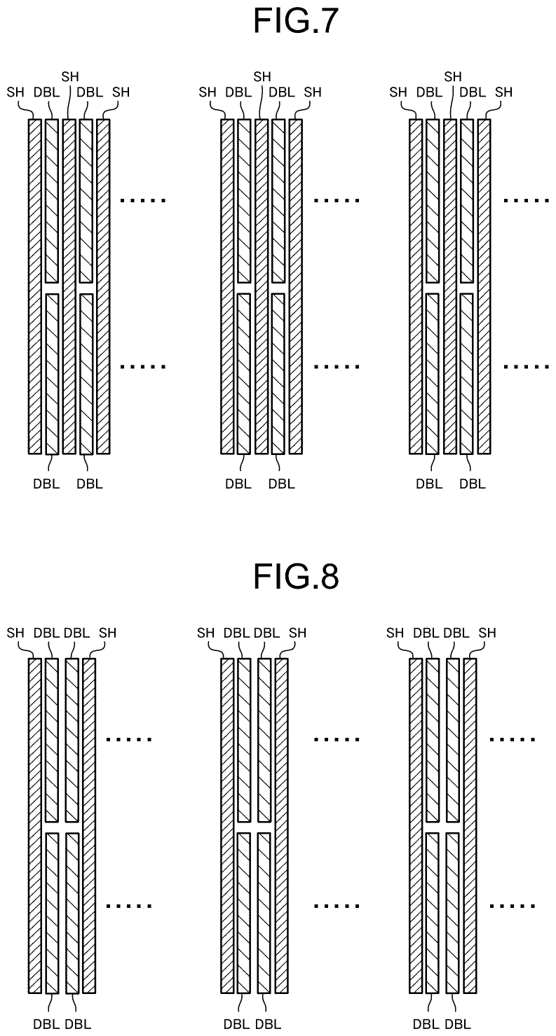

Here, a shield wire having a predetermined potential is disposed in the vicinity of the plurality of intra-module wires DBL. FIGS. 7 and 8 illustrate a configuration example of a shield wire SH.

FIG. 7 is a schematic diagram illustrating an example of a configuration of the shield wire SH disposed in the vicinity of the intra-module wire DBL according to the embodiment. As illustrated in FIG. 7, the shield wire SH is disposed between the plurality of intra-module wires DBL disposed in the same group GR side by side in the X direction and on both sides in the X direction.

These shield wires SH can be disposed over the entire extending direction of the plurality of intra-module wires DBL arranged in the Y direction. That is, for example, three shield wires SH are disposed for four intra-module wires DBL disposed in one group GR.

In addition, the shield wires SH are maintained at a predetermined potential as described above. These shield wires SH may be maintained at different potentials.

As a result, the individual intra-module wires DBL are separated from each other, and the effect of noise or the like between the adjacent intra-module wires DBL is suppressed.

FIG. 8 is a schematic diagram illustrating another example of a configuration of the shield wire SH disposed in the vicinity of the intra-module wire DBL according to the embodiment. In the example illustrated in FIG. 8, the shield wire SH is not disposed between the plurality of intra-module wires DBL disposed in the same group GR side by side in the X direction.

Different voltages may be applied to the plurality of intra-module wires DBL arranged in the X direction during the electrical operation of the corresponding memory cells MC. In addition, among these voltages, the highest voltage can be applied at the time of data erasure. However, the voltage applied at the time of data erasure is constant between these intra-module wires DBL.

Accordingly, even when the plurality of intra-module wires DBL arranged in the X direction is collectively separated from other wires or the like by a set of shield wires SH sandwiching the plurality of intra-module wires DBL from both sides in the X direction as in the example of FIG. 8, noise in the intra-module wires DBL can be sufficiently reduced.

### OVERVIEW

The semiconductor memory device includes, for example, a plurality of sense amplifier units that reads data of a plurality of memory cells. In addition, the memory cell array in which the plurality of memory cells is disposed and the sense amplifier module including the plurality of sense amplifier units are disposed apart from each other in, for example, the up-down direction. However, the width of the sense amplifier module in the X direction is narrower than the width of the memory cell region in the X direction, and the memory cell that does not overlap the sense amplifier module in the up-down direction is connected to the corresponding sense amplifier unit by a wire extending to the sense amplifier module in the X direction.

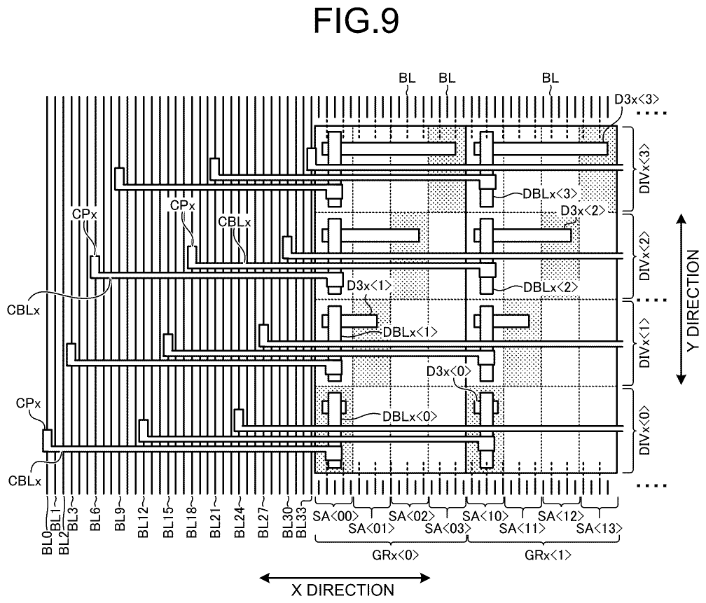

FIG. 9 is a layout diagram illustrating a connection relationship between pillars and sense amplifier units SA according to a comparative example. As illustrated in FIG. 9, in a semiconductor memory device of the comparative example, four intra-module wires DBLx included in one group GRx are disposed in a row side by side in the Y direction. Accordingly, the plurality of sense amplifier units SA is divided into four regions DIVX in the Y direction.

An intra-module wire DBLx<0> disposed in a region DIVX<0> of the sense amplifier unit SA is connected to the sense amplifier unit SA immediately below a wire D3x<0> in the region DIVx<0> via the wire D3x<0> disposed in the region DIVx<0>.

An intra-module wire DBLx<1> disposed in a region DIVx<1> of the sense amplifier unit SA is connected, in the region DIVx<1>, to the sense amplifier unit SA adjacent to the sense amplifier unit SA to which the wire D3x<0> is connected in the X direction via a wire D3x<1> disposed in the region DIVx<1>.

An intra-module wire DBLx<2> disposed in a region DIVx<2> of the sense amplifier unit SA is connected, in the region DIVx<2>, to the sense amplifier unit SA adjacent to the sense amplifier unit SA to which the wire D3x<1> is connected in the X direction via a wire D3x<2> disposed in the region DIVx<2>.

An intra-module wire DBLx<3> disposed in a region DIVx<3> of the sense amplifier unit SA is connected, in the region DIVx<3>, to the sense amplifier unit SA adjacent to the sense amplifier unit SA to which the wire D3x<2> is connected in the X direction via a wire D3x<3> disposed in the region DIVx<3>.

As a result, the plurality of inter-cell module wires CBLx connected to the plurality of bit lines BL is disposed in the regions DIVx<0> to DIVX<3> in a distributed manner. Accordingly, the plugs V2, the pads PDm and PDC, and the plugs C5 connecting the plurality of inter-cell module wires CBLx and the corresponding intra-module wires DBLx are also disposed in the regions DIVx<0> to DIVx<3> in a distributed manner.

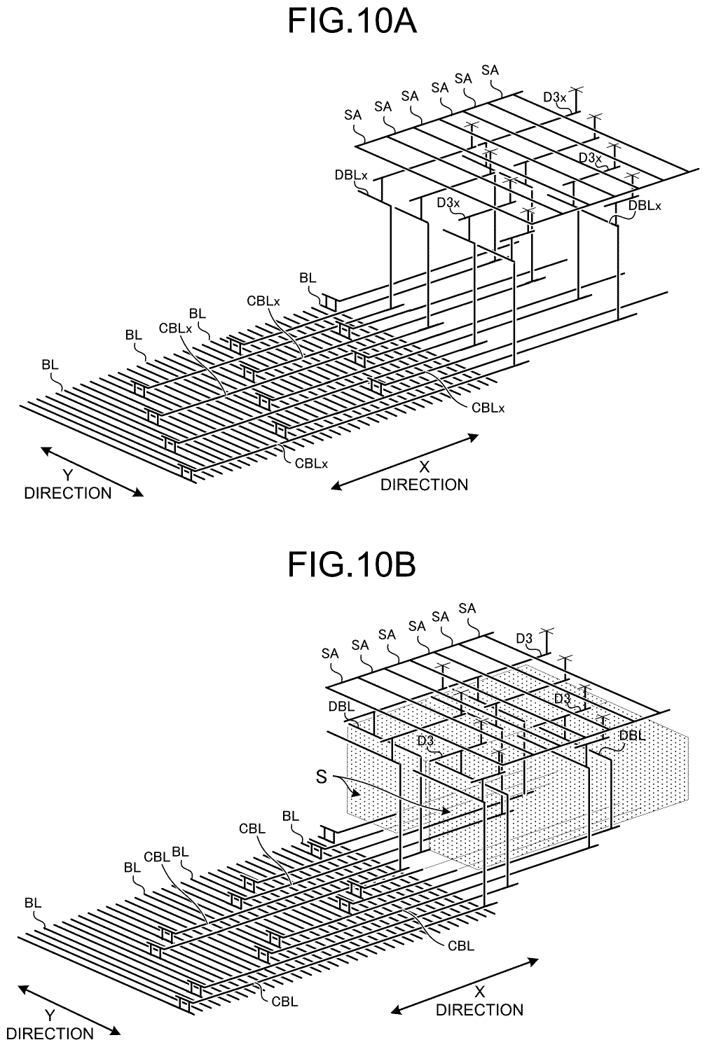

A connection relationship between the bit lines BL and the sense amplifier units SA at this time is three-dimensionally illustrated in FIG. 10A. FIG. 10B illustrates the three-dimensional structure of the semiconductor memory device 1 of the embodiment illustrated in FIG. 6B described above again for reference.

As illustrated in FIG. 10A, in the semiconductor memory device of the comparative example, four intra-module wires DBLx are disposed in four regions DIVX side by side in the Y direction. As a result, the extending distance of the individual intra-module wires DBLx in the Y direction is shortened, and when the necessary number of inter-cell module wires CBLx are disposed at positions overlapping the corresponding intra-module wires DBLx, the pitch between the inter-cell module wires CBLx is narrowed. On the other hand, when the pitch between the inter-cell module wires CBLx is increased, the width of the sense amplifier unit SA in the Y direction is increased.

In addition, in the semiconductor memory device of the comparative example, as described above, the plugs V2, the pads PDm and PDc, and the plugs C5 connecting the plurality of inter-cell module wires CBLx and the intra-module wires DBLx are disposed in the regions DIVx<0> to DIVX<3> in a distributed manner. Therefore, a sufficient space is not secured in the layer between the plurality of inter-cell module wires CBLx and the plurality of intra-module wires DBLX.

In addition, since the plurality of inter-cell module wires CBLx is also dispersedly disposed for each of the corresponding plurality of intra-module wires DBLx, the interval between the inter-cell module wires CBLx connected to the different intra-module wires DBLx is relatively narrowed. Therefore, the length in the Y direction of a connection portion CPx between each inter-cell module wire CBLx and the corresponding bit line BL is restricted.

The semiconductor memory device has a large number of other wires belonging to the layer between the plurality of inter-cell module wires CBLx and the plurality of intra-module wires DBLx and not related to the connection between the bit lines BL and the sense amplifier units SA. When such wires are to be disposed in a region between the plurality of inter-cell module wires CBLx and the plurality of intra-module wires DBLx, it is necessary to dispose these wires while avoiding the plugs V2, the pads PDm and PDc, the plugs C5, and the like connecting the inter-cell module wires CBLx and the intra-module wires DBLx, and the wire structure becomes complicated.

The semiconductor memory device 1 according to the embodiment includes the inter-cell module wires CBL electrically connected to the predetermined memory cells MC and extending in the direction along the X direction from the position overlapping the memory cells MC in the up-down direction toward the sense amplifier module 530, and the intra-module wires DBL extending in the direction along the Y direction side by side with other intra-module wires DBL in the X direction at the position close to the intra-module wires DBL to which other inter-cell module wires CBL are connected, and electrically connecting the inter-cell module wires CBL and the sense amplifier units SA corresponding thereto.

As illustrated in FIG. 10B, with the above configuration, in the semiconductor memory device 1 of the embodiment, a sufficient space S is secured in the layer between the plurality of inter-cell module wires CBL and the plurality of intra-module wires DBL.

Accordingly, other wires belonging to the layer between the plurality of inter-cell module wires CBL and the plurality of intra-module wires DBL and not related to the connection between the bit lines BL and the sense amplifier units SA can be disposed using the aforementioned space S. As a result, the degree of freedom in the disposition of other wires is increased, so that it is possible to suppress the wire structure from becoming complicated.

In addition, since the plurality of inter-cell module wires CBL is also collectively disposed for each of the corresponding plurality of intra-module wires DBL, the interval between the inter-cell module wires CBL connected to the different intra-module wires DBL can be made relatively wide. For example, because a long connection portion CP between each inter-cell module wire CBL and the corresponding bit line BL in the Y direction can be secured, the reliability of the electrical connection between each inter-cell module wire CBL and the corresponding bit line BL can be enhanced.

Therefore, in the semiconductor memory device 1, the bit lines BL, the inter-cell module wires CBL, the intra-module wires DBL, and the like can be efficiently wired.

With the semiconductor memory device 1 of the embodiment, the number of sense amplifier units SA included in one group GR among the plurality of groups GR is larger than the number of the plurality of regions DIV. In such a configuration, in one sense amplifier unit SA, the distance in which the intra-module wire DBL extends in the Y direction is long. As a result, it is possible to suppress narrowing of the pitch of the plurality of inter-cell module wires CBL and an increase in the width of the sense amplifier units SA in the Y direction.

With the semiconductor memory device 1 of the embodiment, a plurality of intra-module wires DBL is disposed in a predetermined region of the sense amplifier module 530 partitioned by one group GR and one region DIV among the plurality of regions DIV. As described above, since the plurality of intra-module wires DBL arranged in the X direction are disposed close to each other in a very limited predetermined region of the sense amplifier module 530, the plugs V2, the pads PDm and PDc, the plugs C5, and the like associated therewith are also concentrated in the predetermined region. Thus, a larger space S can be secured in the layer between the plurality of inter-cell module wires CBL and the plurality of intra-module wires DBL.

With the semiconductor memory device 1 of the embodiment, the number of sense amplifier units SA included in one group GR is equal to the number of intra-module wires DBL disposed in one group GR. As a result, each of the sense amplifier units SA in one group GR can be connected to the corresponding inter-cell module wire CBL via these intra-module wires DBL.

The semiconductor memory device 1 of the embodiment includes the shield wires SH disposed on both sides in the X direction of the plurality of intra-module wires DBL arranged in the X direction and having a predetermined potential. As a result, noise between the plurality of intra-module wires DBL can be suppressed.

Note that, in the above-described embodiment, the intra-module wires DBL connecting the inter-cell module wires CBL and the wires D3 on the sense amplifier unit SA side are disposed in one layer. However, by configuring the wires D4 as a multilayer wire disposed in a plurality of layers, the intra-module wires DBL may also be multilayered. That is, one inter-cell module wire CBL and one corresponding wire D3 may be connected by a plurality of intra-module wires DBL disposed over a plurality of layers.

In this case, at least the above-described shield wires SH can be provided with respect to the intra-module wire DBL disposed closest to the memory cell array and connected to the inter-cell module wire CBL and the intra-module wire DBL disposed closest to the sense amplifier units SA and connected to the wires D3 among the plurality of intra-module wires DBL. However, each of the individual intra-module wires DBL of the plurality of layers may have the shield wire SH.

### MODIFICATION

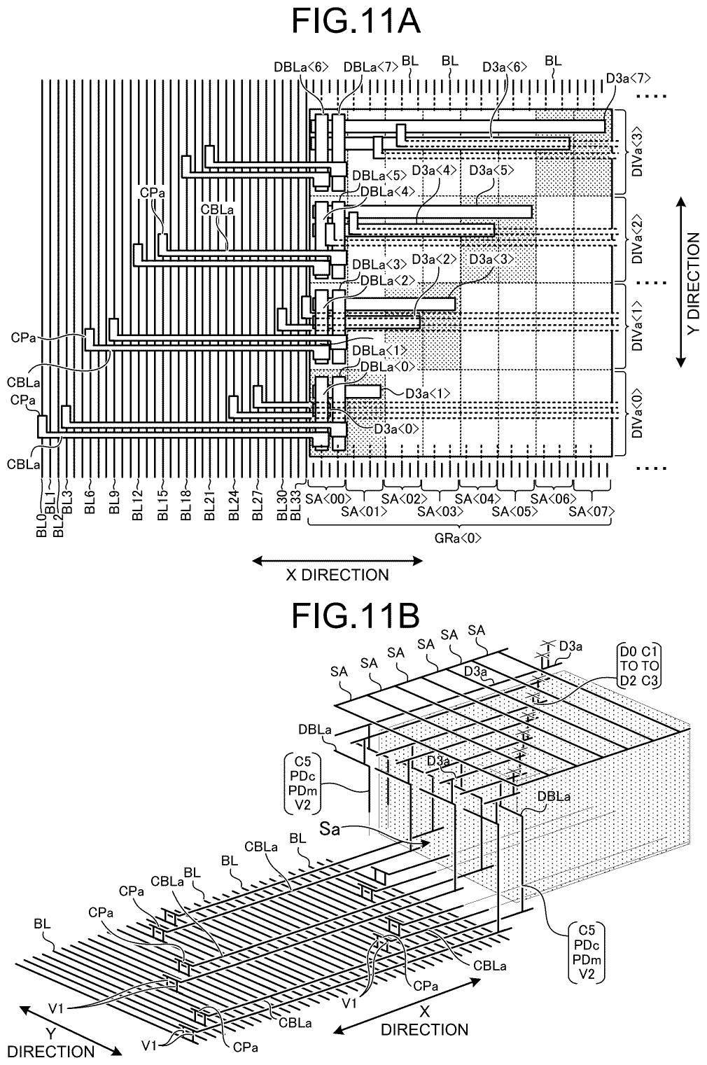

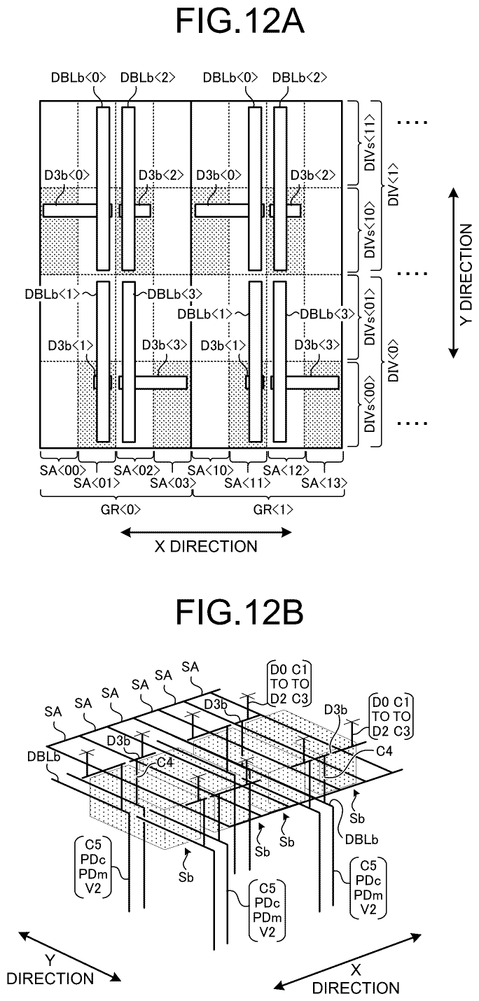

Next, semiconductor memory devices of first and second modifications of the embodiment will be described with reference to FIGS. 11A to 12B. In the description below, the same reference numerals are given to the same configurations as those of the embodiment described above, and the description thereof may be omitted.

### First Modification

FIGS. 11A and 11B are diagrams illustrating an example of a wire structure that electrically connects pillars PL and sense amplifier units SA included in a semiconductor memory device according to a first modification of the embodiment. More specifically, FIG. 11A is a layout diagram illustrating a connection relationship between pillars PL and sense amplifier units SA. FIG. 11B is a schematic diagram three-dimensionally illustrating a connection relationship between the pillars PL and the sense amplifier units SA.

In the semiconductor memory device of the first modification, the number of sense amplifier units SA included in one group GRa and regions DIVa included in each of the plurality of sense amplifier units SA are different from those of the above-described embodiment.

As illustrated in FIGS. 11A and 11B, in the semiconductor memory device of the first modification, eight sense amplifier units SA are included in one group GRa. FIGS. 11A and 11B illustrate sense amplifier units SA<00> to SA<07> included in one group GRa<0>.

These sense amplifier units SA are divided into four regions DIVa<0> to DIVa<3> in the Y direction. In other words, among these sense amplifier units SA, in the sense amplifier unit SA<00>, four intra-module wires DBLa arranged in the Y direction are disposed in two columns, and individual sense amplifier units SA are divided into the four regions DIVa<0> to DIVa<3> accordingly.

Among eight intra-module wires DBLa in one group GRa, two intra-module wires DBLa<0> and DBLa<1> extend in the Y direction side by side in the X direction in the region DIVa<0> in the sense amplifier unit SA<00>.

Among these intra-module wires DBLa<0> and DBLa<1>, the intra-module wire DBLa<0> is connected to an inter-cell module wire CBLa electrically connected to the bit line BL0 in the region DIVa<0> of the sense amplifier unit SA<00>, and is connected to the sense amplifier unit SA<00> in the region DIVa<0> via the wire D3<0> disposed in the region DIVa<0>.

Note that, also in the semiconductor memory device of the first modification, a connection portion CPa extending in the Y direction can also be provided because a long connection is secured in the Y direction between each inter-cell module wire CBLa and the corresponding bit line BL.

In addition, the intra-module wire DBLa<1> is connected to an inter-cell module wire CBLa connected to the bit line BL3 in the region DIVa<0> of the sense amplifier unit SA<00>, and is connected to the sense amplifier unit SA<01> adjacent in the X direction to the sense amplifier unit SA<00> to which the wire D3<0> is connected in the region DIVa<0> via the wire D3<1> disposed in the region DIVa<0> and extending in the X direction.

Among the eight intra-module wires DBLa in one group GRa, two intra-module wires DBLa<2> and DBLa<3> are arranged in the Y direction with the intra-module wires DBLa<0> and DBLa<1> and extend in the Y direction side by side in the X direction in the region DIVa<1> of the sense amplifier unit SA<00>.

Among them, the intra-module wire DBLa<2> is connected to an inter-cell module wire CBLa connected to the bit line BL6 in the region DIVa<1> of the sense amplifier unit SA<00>, and is connected to the sense amplifier unit SA<02> adjacent in the X direction to the sense amplifier unit SA<01> to which the wire D3<1> is connected in the region DIVa<1> via the wire D3<2> disposed in the region DIVa<1> and extending in the X direction. In addition, the intra-module wire DBLa<3> is connected to an inter-cell module wire CBLa connected to the bit line BL9 in the region DIVa<1> of the sense amplifier unit SA<00>, and is connected to the sense amplifier unit SA<03> adjacent in the X direction to the sense amplifier unit SA<02> to which the wire D3<2> is connected in the region DIVa<1> via the wire D3<3> disposed in the region DIVa<1> and extending in the X direction.

Among the eight intra-module wires DBLa in one group GRa, two intra-module wires DBLa<4> and DBLa<5> are arranged in the Y direction with the intra-module wires DBLa<0> and DBLa<2> and the intra-module wires DBLa<1> and DBLa<3> and extend in the Y direction side by side in the X direction in the region DIVa<2> of the sense amplifier unit SA<00>.

Among them, the intra-module wire DBLa<4> is connected to an inter-cell module wire CBLa connected to the bit line BL12 in the region DIVa<2> of the sense amplifier unit SA<00>, and is connected to the sense amplifier unit SA<04> adjacent in the X direction to the sense amplifier unit SA<03> to which the wire D3<3> is connected in the region DIVa<2> via the wire D3<4> disposed in the region DIVa<2> and extending in the X direction. In addition, the intra-module wire DBLa<5> is connected to an inter-cell module wire CBLa connected to the bit line BL15 in the region DIVa<2> of the sense amplifier unit SA<00>, and is connected to the sense amplifier unit SA<05> adjacent in the X direction to the sense amplifier unit SA<04> to which the wire D3<4> is connected in the region DIVa<2> via the wire D3<5> disposed in the region DIVa<2> and extending in the X direction.

Among the eight intra-module wires DBLa in one group GRa, two intra-module wires DBLa<6> and DBLa<7> are arranged in the Y direction with the intra-module wires DBLa<0>, DBLa<2>, and DIVa<4> and the intra-module wires DBLa<1>, DBLa<3>, and DIVa<5>, and extend in the Y direction side by side in the X direction in the region DIVa<3> of the sense amplifier unit SA<00>.

Among them, the intra-module wire DBLa<6> is connected to an inter-cell module wire CBLa connected to the bit line BL18 in the region DIVa<3> of the sense amplifier unit SA<00>, and is connected to the sense amplifier unit SA<06> adjacent in the X direction to the sense amplifier unit SA<05> to which the wire D3<5> is connected in the region DIVa<3> via the wire D3<6> disposed in the region DIVa<3> and extending in the X direction. In addition, the intra-module wire DBLa<7> is connected to an inter-cell module wire CBLa connected to the bit line BL21 in the region DIVa<3> of the sense amplifier unit SA<00>, and is connected to the sense amplifier unit SA<07> adjacent in the X direction to the sense amplifier unit SA<06> to which the wire D3<6> is connected in the region DIVa<3> via the wire D3<7> disposed in the region DIVa<3> and extending in the X direction.

As a result, substantially the entire region overlapping the sense amplifier units SA<01> to SA<07> in the up-down direction is secured as one sufficient space Sa in the layer between the plurality of inter-cell module wires CBLa and the plurality of intra-module wires DBLa.

With the semiconductor memory device of the first modification, the wider space Sa is secured by the above configuration.

With the semiconductor memory device of the first modification, the same effects as those of the above-described embodiment are obtained.

### Second Modification

FIGS. 12A and 12B are diagrams illustrating an example of a wire structure that electrically connects pillars PL and sense amplifier units SA included in a semiconductor memory device according to a second modification of the embodiment. More specifically, FIG. 12A is a layout diagram of sense amplifier units SA. FIG. 12B is a schematic diagram three-dimensionally illustrating a connection relationship mainly in the sense amplifier units SA.

The semiconductor memory device of the second modification is different from the semiconductor memory device of the above-described embodiment in the position where intra-module wires DBLb are disposed.

As illustrated in FIGS. 12A and 12B, in the semiconductor memory device according to the second modification, grouping and region division of the plurality of sense amplifier units SA are similar to those in the above-described embodiment. That is, one group GR includes four sense amplifier units SA adjacent to each other in the X direction, and these sense amplifier units SA are divided into two regions DIV each including two sub-regions DIVs in the Y direction.

In one group GR, four intra-module wires DBL are disposed as in the above-described embodiment. However, these four intra-module wires DBLb are disposed in two sense amplifier units SA at the center in the X direction among the four sense amplifier units SA arranged in the X direction in the group GR.

More specifically, among the four intra-module wires DBLb disposed in a group GA<0>, an intra-module wire DBLb<1> extends in the Y direction across sub-regions DIVs<00> and DIVs<01> of the sense amplifier unit SA<01>, and is connected to the sense amplifier unit SA<01> in the sub-region DIVs<00> via a wire D3b<1> disposed in the sub-region DIVs<00>.

In addition, an intra-module wire DBLb<3> extends in the Y direction side by side with the intra-module wire DBLb<1> in the X direction across the sub-regions DIVs<00> and DIVs<01> of the sense amplifier unit SA<02>, and is connected to the sense amplifier unit SA<03> in the sub-region DIVs<00> via a wire D3b<3> disposed in the sub-region DIVs<00>.

In addition, an intra-module wire DBLb<0> extends in the Y direction side by side with the intra-module wire DBLb<1> in the Y direction across the sub-regions DIVs<10> and DIVs<11> of the sense amplifier unit SA<01>, and is connected to the sense amplifier unit SA<00> in the sub-region DIVs<10> via a wire D3b<0> disposed in the sub-region DIVs<10>.

In addition, an intra-module wire DBLb<2> extends in the Y direction side by side with the intra-module wire DBLb<0> in the X direction across the sub-regions DIVs<10> and DIVs<11> of the sense amplifier unit SA<02>, and is connected to the sense amplifier unit SA<02> in the sub-region DIVs<10> via a wire D3b<2> disposed in the sub-region DIVs<10>.

Note that four intra-module wires DBLb<0> to DBLb<3> included in a group GR<1> and wires D3b<0> to D3b<3> connected thereto are configured similarly to intra-module wires DBLb and wires D3b in a group GR<0>.

With the above configuration, in the semiconductor memory device of the second modification, the plurality of plugs C4 connecting the intra-module wires DBLb and the wires D3b are collectively disposed at the central part in the X direction in the group GR. As a result, a sufficient space Sb is also secured in the layer between the intra-module wires DBLb and the wires D3b.

With the semiconductor memory device of the second modification, the same effects as those of the above-described embodiment are obtained.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array that includes a plurality of memory cells;
a sense amplifier module that includes a plurality of sense amplifier units disposed at positions overlapping the memory cell array in an up-down direction and arranged in a first direction intersecting the up-down direction, the sense amplifier module having a width in the first direction narrower than a width of the memory cell array; and
a plurality of bit lines that connects a sense amplifier unit among the plurality of sense amplifier units and a memory cell among the plurality of memory cells corresponding to each other, wherein
the plurality of bit lines includes
a first bit line connecting a first memory cell among the plurality of memory cells and a first sense amplifier unit corresponding to the first memory cell among the plurality of sense amplifier units, and
a second bit line connecting a second memory cell among the plurality of memory cells and a second sense amplifier unit corresponding to the second memory cell among the plurality of sense amplifier units,
the first bit line includes
a first inter-cell module wire electrically connected to the first memory cell and extending in the first direction toward the sense amplifier module from a position overlapping the first memory cell in the up-down direction, and
a first intra-module wire extending at a position overlapping the sense amplifier module in the up-down direction in a second direction intersecting both the first direction and the up-down direction and electrically connecting the first inter-cell module wire and the first sense amplifier unit, and
the second bit line includes
a second inter-cell module wire electrically connected to the second memory cell and extending in the first direction toward the sense amplifier module from a position overlapping the second memory cell in the up-down direction, and
a second intra-module wire extending at a position close to the first intra-module wire in the second direction side by side in the first direction with the first intra-module wire, and electrically connecting the second inter-cell module wire and the second sense amplifier unit.

2. The semiconductor memory device according to claim 1, wherein
the first and second sense amplifier units are adjacent to each other in the first direction, and
the first and second intra-module wires extend in the second direction side by side in the first direction at positions overlapping the first sense amplifier unit in the up-down direction.

3. The semiconductor memory device according to claim 1, wherein
the first bit line further includes a first intra-cell wire extending in the second direction at a position overlapping the first memory cell in the up-down direction and electrically connecting the first memory cell and the first inter-cell module wire, and
the second bit line further includes a second intra-cell wire extending in the second direction at a position overlapping the second memory cell in the up-down direction and electrically connecting the second memory cell and the second inter-cell module wire.

4. The semiconductor memory device according to claim 3, wherein
the first and second intra-cell wires, the first and second inter-cell module wires, and the first and second intra-module wires are disposed in different layers between the memory cell array and the sense amplifier module in this order from a memory cell array side toward a sense amplifier module side.

5. The semiconductor memory device according to claim 1, further comprising:
a shield wire that sandwiches from both sides in the first direction of the first and second intra-module wires arranged in the first direction and has a predetermined potential.

6. The semiconductor memory device according to claim 1, wherein
the plurality of bit lines includes
a third bit line connecting a third memory cell among the plurality of memory cells and a third sense amplifier unit corresponding to the third memory cell among the plurality of sense amplifier units, and
a fourth bit line connecting a fourth memory cell among the plurality of memory cells and a fourth sense amplifier unit corresponding to the fourth memory cell among the plurality of sense amplifier units,
the third bit line includes
a third inter-cell module wire electrically connected to the third memory cell and extending in the first direction toward the sense amplifier module from a position overlapping the third memory cell in the up-down direction, and
a third intra-module wire extending at a position overlapping the sense amplifier module in the up-down direction in the second direction and electrically connecting the third inter-cell module wire and the third sense amplifier unit, and
the fourth bit line includes
a fourth inter-cell module wire electrically connected to the fourth memory cell and extending in the first direction toward the sense amplifier module from a position overlapping the fourth memory cell in the up-down direction, and
a fourth intra-module wire extending at a position close to the third intra-module wire in the second direction side by side in the first direction with the third intra-module wire, and electrically connecting the fourth inter-cell module wire and the fourth sense amplifier unit.

7. The semiconductor memory device according to claim 6, wherein
the first to fourth sense amplifier units are adjacent in this order in the first direction,
the first and second intra-module wires extend in the second direction side by side in the first direction at a position overlapping the first sense amplifier unit in the up-down direction, and
the third and fourth intra-module wires are disposed side by side with the first and second intra-module wires in the second direction, and extend in the second direction side by side with each other in the first direction.

8. The semiconductor memory device according to claim 7,
the first bit line further includes a first intra-cell wire extending in the second direction at a position overlapping the first memory cell in the up-down direction and electrically connecting the first memory cell and the first inter-cell module wire,
the second bit line further includes a second intra-cell wire extending in the second direction at a position overlapping the second memory cell in the up-down direction and electrically connecting the second memory cell and the second inter-cell module wire,
the third bit line further includes a third intra-cell wire extending in the second direction at a position overlapping the third memory cell in the up-down direction and electrically connecting the third memory cell and the third inter-cell module wire,
the fourth bit line further includes a fourth intra-cell wire extending in the second direction at a position overlapping the fourth memory cell in the up-down direction and electrically connecting the fourth memory cell and the fourth inter-cell module wire, and
the first to fourth intra-cell wires are disposed in this order in the first direction.

9. The semiconductor memory device according to claim 6, wherein
the first, third, second, and fourth sense amplifier units are adjacent in this order in the first direction,
the first and third intra-module wires extend in the second direction side by side with each other in the second direction at a position overlapping the second sense amplifier unit in the up-down direction, and
the second and fourth intra-module wires extend in the second direction side by side with each other in the second direction at a position overlapping the third sense amplifier unit in the up-down direction.

10. The semiconductor memory device according to claim 9, wherein
the first bit line further includes a first intra-cell wire extending in the second direction at a position overlapping the first memory cell in the up-down direction and electrically connecting the first memory cell and the first inter-cell module wire,
the second bit line further includes a second intra-cell wire extending in the second direction at a position overlapping the second memory cell in the up-down direction and electrically connecting the second memory cell and the second inter-cell module wire,
the third bit line further includes a third intra-cell wire extending in the second direction at a position overlapping the third memory cell in the up-down direction and electrically connecting the third memory cell and the third inter-cell module wire,
the fourth bit line further includes a fourth intra-cell wire extending in the second direction at a position overlapping the fourth memory cell in the up-down direction and electrically connecting the fourth memory cell and the fourth inter-cell module wire, and
the first to fourth intra-cell wires are disposed in this order in the first direction.

11. A semiconductor memory device comprising:
a memory cell array that includes a plurality of memory cells;
a sense amplifier module that includes a plurality of sense amplifier units disposed at positions overlapping the memory cell array in an up-down direction and arranged in a first direction intersecting the up-down direction, the sense amplifier module having a width in the first direction narrower than a width of the memory cell array; and
a plurality of bit lines that connects a sense amplifier unit among the plurality of sense amplifier units and a memory cell among the plurality of memory cells corresponding to each other, wherein
each of the plurality of bit lines includes
an inter-cell module wire electrically connected to one memory cell among the plurality of memory cells and extending in the first direction toward the sense amplifier module from a position overlapping the one memory cell in the up-down direction, and
an intra-module wire extending at a position overlapping the sense amplifier module in the up-down direction in a second direction intersecting both the first direction and the up-down direction and electrically connecting the inter-cell module wire and a sense amplifier unit corresponding to the one memory cell among the plurality of sense amplifier units,
the sense amplifier module is
divided, in the first direction, into a plurality of groups each including two or more sense amplifier units adjacent to each other, and
divided, in the second direction, into a plurality of regions allocated for each intra-module wire included in each of the plurality of bit lines and arranged in the second direction, and
a number of sense amplifier units included in one group of the plurality of groups is larger than a number of the plurality of regions.

12. The semiconductor memory device according to claim 11, wherein
the one group includes N (N is an integer of 2 or more) sense amplifier units, and
the number of the plurality of regions included in each of the N sense amplifier units is N/2.

13. The semiconductor memory device according to claim 11, wherein
two or more intra-module wires among a plurality of intra-module wires included in the plurality of bit lines is disposed in a predetermined region of the sense amplifier module defined by the one group and one region among the plurality of regions.

14. The semiconductor memory device according to claim 13, wherein
the plurality of intra-module wires is disposed side by side with each other in the first direction.

15. The semiconductor memory device according to claim 13, wherein
the number of sense amplifier units included in the one group is equal to a number of intra-module wires disposed in the one group among the plurality of intra-module wires included in the plurality of bit lines.
